(19) United States
(12) Patent Application Publication
(10) Pub. No.: US 2024/0219439 A1
(43) Pub. Date: Jul. 4, 2024

(54) POWER DETECTOR

(71) Applicant: STMicroelectronics International N.V., Geneva (CH)

(72) Inventor: Alessandro VENCA, Hauterive (CH)

(73) Assignee: STMicroelectronics International N.V., Geneva (CH)

(21) Appl. No.: 18/541,617

(22) Filed: Dec. 15, 2023

(30) Foreign Application Priority Data
Dec. 22, 2022 (FR) 2214192

(51) Int. Cl. G01R 21/10; H04B 1/16; H04B 17/20; H04B 17/21

(52) U.S. Cl. CPC G01R 21/10; H04B 1/16; H04B 17/202; H04B 17/21; H04B 2001/0416

(57) ABSTRACT

A power detector for detecting the RMS power of an AC voltage includes a transconductor configured to receive the AC voltage and to provide a first current to a node with a non-linear relation between the first current and the voltage. A current output digital to analog converter is configured to receive a digital signal and to provide a second current to the node. A low pass filter is coupled to the node, and an inverter is coupled to the node and configured to provide a binary signal.

### PRIORITY CLAIM

This application claims the priority benefit of French patent application number 2214192, filed on Dec. 21, 2022, which is hereby incorporated by reference to the maximum extent allowable by law.

### TECHNICAL FIELD

The present disclosure concerns a power detector for determining the power of an alternating current (AC) signal.

### BACKGROUND

Root mean square (RMS) power detectors are based on average power measurement, and are particularly suited for making accurate power measurements of radiofrequency modulated signals that exhibit high peak-to-average ratio or noise-like properties.

An RMS power detector can for example be used in a radiofrequency receiver comprising amplifiers and an automatic gain control circuit that can control the gains of the amplifiers based on the RMS power measured by the RMS power detector. A drawback of an RMS power detector is that it may have excessive power consumption. Another drawback of an RMS power detector is that it can have a low sensitivity.

There is a need in the art to provide an RMS power detector overcoming all or part of the disadvantages of existing RMS power detectors.

There is a need in the art for an RMS power detector having a reduced power consumption.

There is a need in the art for an RMS power detector having an enhanced sensitivity.

### SUMMARY

One embodiment provides a power detector for detecting the RMS power of an Ac voltage, including a transconductor configured to receive the voltage and to provide a first current to a node with a non-linear relation between the first current and the voltage, a current output digital to analog converter configured to receive a digital signal and to provide a second current to the node, a low pass filter coupled to the node, and an inverter coupled to the node and configured to provide a binary signal.

According to an embodiment, the transconductor may be a first MOS transistor.

According to an embodiment, the low pass filter may include a first capacitor having an electrode coupled to the node.

According to an embodiment, the current output digital to analog converter may include second MOS transistors and controllable switches, each second MOS transistor being in series with one of the controllable switches, each controllable switch being controlled by one bit of the digital signal.

According to an embodiment, the power detector may include a current source configured to provide a constant reference current and first current mirrors configured to copy the constant reference current multiplied by different multiplying factors, each first current mirror comprising one of the second MOS transistors.

According to an embodiment, the power detector may include a diode mounted third MOS transistor, the gate of the third MOS transistor being coupled to the gate of the first MOS transistor via a resistor and a second current mirror configured to copy the constant reference current to supply the third MOS transistor.

One embodiment also provides an electronic circuit that may include the power detector previously described and an electronic unit configured to receive the binary signal and to vary the digital signal until a toggling of the binary signal.

According to an embodiment, the electronic circuit may be a radiofrequency receiver or a radiofrequency emitter.

According to an embodiment, the electronic circuit may include an amplifier configured to receive a radiofrequency ac voltage and to amplify the radiofrequency ac voltage, the amplifier being a transconductance amplifier comprising a fourth MOS transistor, and the first MOS transistor is a scale replica of the fourth MOS transistor.

One embodiment also provides a method for determining the RMS power of an ac voltage using the power detector previously described, potentially including varying the digital signal until the toggling of the binary signal.

According to an embodiment, the method may also include setting the AC voltage at a constant value, and varying the digital signal until the toggling of the binary signal and storing the digital signal for which the binary signal has toggled.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 partially and schematically shows an embodiment of a power detector;

FIG. 2 is a block diagram of an embodiment of a method for calibrating the power detector shown in FIG. 1;

FIG. 3 partially and schematically shows an embodiment of a current output Digital to Analog converter;

FIG. 4 partially and schematically shows another embodiment of a power detector;

FIG. 5 partially and schematically shows another embodiment of a power detector; and

FIG. 6 partially and schematically shows an embodiment of a radiofrequency receiver circuit.

### DETAILED DESCRIPTION

Like features have been designated by like references in the various figures. In particular, the structural and/or functional features that are common among the various embodiments may have the same references and may dispose identical structural, dimensional, and material properties. For the sake of clarity, only the steps and elements that are useful for an understanding of the embodiments described herein have been illustrated and described in detail.

Unless indicated otherwise, when reference is made to two elements connected together, this signifies a direct electrical connection without any intermediate elements other than conductors, and when reference is made to two elements coupled together, this signifies that these two elements can be connected, or that they can be coupled via one or more other elements. Further, a signal which alternates between a first constant state, for example, a low state, noted “0”, and a second constant state, for example, a high state, noted “1”, is called a “binary signal”. The high and low states of different binary signals of a same electronic circuit may be different. In practice, the binary signals may correspond to voltages or to currents which may not be perfectly constant in the high or low state.

Unless specified otherwise, the expressions “around”, “approximately”, “substantially” and “in the order of” signify within 10%, and preferably within 5%. Further the expression “substantially constant” means which varies by less than 10% over time with respect to a reference value.

The RMS value of an AC signal is defined as the amount of DC signal required to produce an equivalent amount of heat in the same load. Therefore, the RMS voltage Vᵣₘₛ of an AC voltage V is given by the following relation:

$${V}_{rms} = \sqrt{avg [ {V}^{2} ( t ) ]} \qquad ( 1 )$$

The power P(dBm) of an AC signal V, expressed in dBm, is given by the following relation:

$$P ( dBm ) = 10 {log}_{10} ( \frac{\frac{{V}_{rms}^{2}}{50}}{1 mW} ) = 10 {log}_{10} ( \frac{\frac{avg [ {V}_{( t )}^{2} ]}{50}}{1 mW} ) \qquad ( 2 )$$

According to an embodiment, the RMS power detector comprises, in order to realize the power detection of the input AC voltage, a transconductor receiving the input AC voltage and providing an output current and having a non-linear characteristic between the output current and the input voltage. The transconductor can be a metal-oxide-semiconductor field-effect transistor, called MOS transistor hereafter.

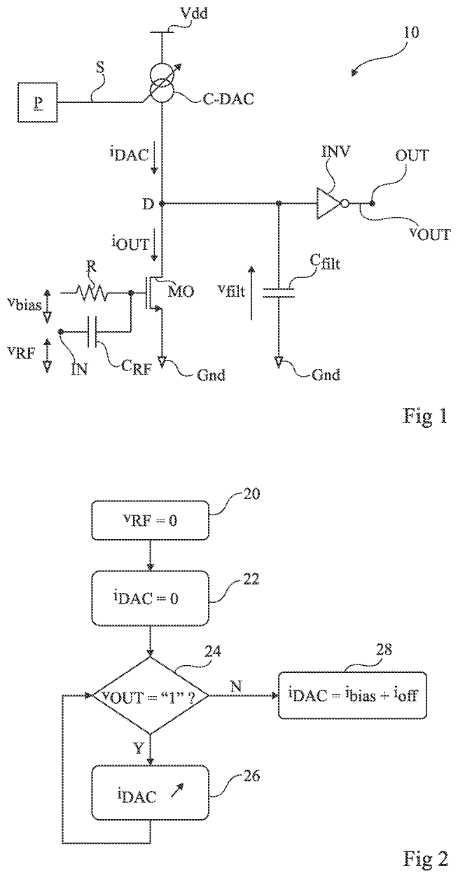

FIG. 1 partially and schematically shows an embodiment of a power detector 10 configured to determine the RMS power of a signal V_{RF}, for example a radiofrequency AC voltage. Power detector 10 is coupled between a source of a high reference potential Vdd and a source of a low reference potential Gnd, for example the ground taken equal to 0V.

Power detector 10 comprises: an input IN receiving voltage V_{RF}; an output OUT providing a binary voltage v_{OUT}; a MOS transistor M0 , for example an N-channel MOS transistor, the source of transistor M0 being coupled or connected to the source of the low reference potential Gnd, the drain of transistor M0 being coupled or connected, to a node D; a current output Digital to Analog converter C-DAC controlled by a digital control signal S and coupled or connected, between node D and the source of the high reference potential Vdd; a resistor R coupled or connected, between the gate of transistor M0 and a source of a biasing voltage v_{bias}; a first capacitor C_{RF} coupled or connected, between input IN and the gate of transistor M0; a second capacitor C_{filt} coupled or connected, between node D and the source of the low reference potential Gnd; and an inverter INV, the input of inverter INV being coupled or connected, to node D, and the output of inverter INV being coupled or connected to output OUT.

Power detector 10 is controlled by a control electronic circuit P, for example a microcontroller, receiving binary voltage v_{OUT} and providing control signal S.

The operation of detector 10 is now described. The converter C-DAC provides a current i_{DAC} at node D that depends on control signal S. Control signal S is a digital signal having N+1 bits S₀ to S_{N}, N being an integer for example greater than or equal to 3. Bit S₀ is for example the least significant bit of control signal S. The current at the drain of transistor M0 is denoted as İOUT and the gate-source voltage of transistor M0 is denoted as led V_{gs}. The first derivative of current jour with respect to voltage V_{gs} is denoted as gm and the second derivative of current i_{OUT} with respect to voltage V_{gs} is denoted as gm′. When voltage V_{RF} is equal to 0V, current i_{OUT} is equal to a constant current i_{bias}. The voltage across capacitor C_{filt} is called v_{filt}.

Without taking into account the filtering action of capacitor C_{filt}, current i_{OUT} is given by the following relation, neglecting the terms higher than the second order terms:

$${i}_{OUT} = {i}_{bias} + gm \cdot {v}_{RF} + {gm}^{′} \cdot {v}_{RF}^{2} \qquad ( 3 )$$

When voltage V_{RF} is a sinusoidal voltage with a pulsation @ and an maximum amplitude V_{RF}, input voltage V_{RF} is given by equation:

$${v}_{RF} = {V}_{RF} \cdot cos ( ω t ) \qquad ( 4 )$$

Equation 3 then becomes:

$${i}_{OUT} = {i}_{bias} + gm \cdot {V}_{RF} \cdot cos ( ω t ) + {gm}^{′} \cdot {V}_{RF}^{2} \cdot {( cos ( ω t ) )}^{2} \qquad ( 5 )$$

Current i_{OUT} is averaged by the filtering action of capacitor C_{filt}, so that actual current i_{OUT} is given by the following equation:

$${i}_{OUT} = {i}_{bias} + \frac{1}{2} {gm}^{′} \cdot {V}_{RF}^{2} \qquad ( 6 )$$

In Equation 6 of current i_{OUT}, the second term is proportional to the RMS power of voltage v_{RF}. Detector 10 senses the DC amplitude of the second order distortion product generated by the non-linear characteristics of MOS transistor M0 by comparing current jour with current i_{DAC} generated by converter C-DAC and by detecting when current i_{DAC} is equal current i_{OUT}.

According to an embodiment, converter C-DAC is controlled so that current i_{DAC} is increased from a 0 A. Therefore, initially current i_{DAC} is inferior to the maximum current jour than can be conducted by transistor M0 . Voltage v_{filt} is therefore substantially at the low reference voltage Gnd. Voltage v_{OUT} is at logical value “1”. Control S is modified to increase current i_{DAC}. As soon as current i_{DAC} becomes superior to the maximum current i_{OUT} than can be conducted by transistor M0 , voltage v_{filt} is driven by transistor M0 and increases to be substantially equal to the high reference voltage Vdd minus the voltage across the converter C-DAC and is superior to the threshold of inverter INV. Voltage v_{filt} therefore decreases instantly above the threshold of inverter INV so that voltage v_{OUT} is at a low logical value “0”. Therefore, voltage v_{OUT} toggles from a high logical value “1” to a low logical value “0” when current i_{DAC} is equal to current i_{OUT}. The toggling of voltage v_{OUT} is detected by control circuit P and the value S_{tog} of control signal S for which voltage v_{OUT} toggles from a high logical value “1” to a low logical value “0” is stored.

Since current i_{bias} is known, the second term of Equation 6 can be determined.

Detector 10 compares in a single branch the drain current i_{OUT} of transistor M0 with a calibrated current i_{DAC} by using voltage V_{filt} at node D that is a high-gain rail-to-rail node, so that the comparison can be performed by a simple inverter INV.

Transistor M0 can controlled in the active region, the triode region, or the weak inversion region. In the active region and the triode region, the relationship i_{ds}/v_{gs} is quadratic, with i_{ds} being the drain to source current and v_{gs} being the gate to source voltage. In the weak inversion region, the relationship i_{ds}/v_{gs} is exponential. In the active region, the triode region, or the weak inversion region, current i_{OUT} carries a term linearly proportional to the RF RMS input power, so that the detection method previously described can be implemented.

Due to the mismatch of the components of detector 10, there may be an extra DC term i_{off} that appears in the Equation 6 of current i_{OUT}, which becomes the following:

$${i}_{OUT} = {i}_{bias} + \frac{1}{2} {gm}^{′} \cdot {V}_{RF}^{2} + {i}_{off} \qquad ( 7 )$$

FIG. 2 is a block diagram illustrating an embodiment of a calibration method of detector 10 to take into account the extra term i_{off}.

At step 20, voltage v_{RF} is set to 0V.

At step 22, converter C-DAC is controlled so that current i_{DAC} is equal to 0A.

At step 24, voltage v_{OUT} is observed. In case voltage v_{OUT} is equal to high logical value “1” (Y), the method goes on to step 26. In case voltage v_{OUT} is equal to low logical value “0” (N), the method continues at step 28.

At step 26, control signal S is increased, for example, by one bit. This leads to an increase of current i_{DAC}. The method goes back at step 24 in which voltage v_{OUT} is observed.

At step 28, the toggling of voltage v_{OUT} is detected by control circuit P and the value S_{off} of control value S is stored. Since voltage v_{OUT} has just toggled from high logical value “1” to low logical value “0”, current i_{DAC} corresponding to stored control value S_{off} is equal to the sum of i_{bias} and i_{off}.

According to another embodiment, the determination of value S_{off} of control signal S can be made by a dichotomy algorithm.

When value S_{tog} of control signal S for which voltage v_{OUT} toggles from a high logical value “1” to a low logical value “0” is detected, the difference between values S_{tog} and S_{off} can be determined.

The method for determining control value S_{off} can be implemented at the startup of the electronic device comprising detector 10. Values S_{off} and S_{tog} of control signal S can be used to determine the second term of Equation 6 that is proportional to the RMS power of voltage V_{RF}.

The previously described method for determining control value S_{off} advantageously does not require additional analog hardware to be implemented. Moreover, it advantageously does not require voltage v_{RF}.

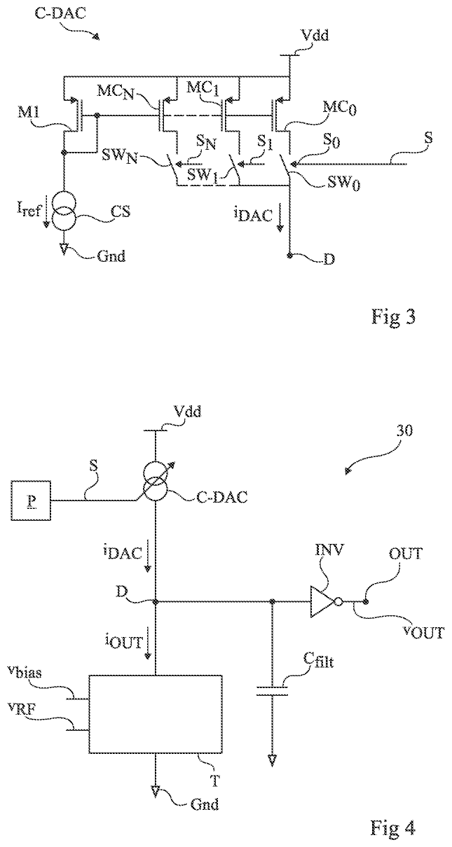

FIG. 3 shows an embodiment of current output Digital to Analog converter C-DAC.

Current output Digital to Analog converter C-DAC comprises: a current source CS providing a constant current I_{ref} and having a first terminal coupled or connected to the source of the low reference potential Gnd; a MOS transistor M1, for an example a P channel MOS transistor, the source of transistor M1 being coupled or connected to the source of the high reference potential Vdd, the drain of transistor M1 being coupled or connected, to a second terminal of current source CS, and the gate of transistor M1 being coupled or connected, to the second terminal of current source CS; N+1 MOS transistors MCᵢ, i being a integer varying from 0 to N, each transistor MCᵢ being for example a P channel MOS transistor, the source of transistor MCᵢ being coupled or connected to the source of the high reference potential Vdd, and the gate of transistor MCᵢ being coupled or connected, to the gate of transistor M1; and N+1 controllable switches SWᵢ, i being a integer varying from 0 to N, each switch SWᵢ having a first terminal coupled or connected to the drain of transistor MCᵢ and a second terminal coupled or connected to node D, each switch SWᵢ being controlled by bit Sᵢ of control signal S.

Each transistor MCᵢ has a size factor with respect to transistor M1 equal to 2ⁱ. This means that transistor MC₀ has the same size as transistor M1 and that transistor MC_{N} is 2^{N} times bigger than transistor M1. Each transistor MCᵢ forms a current mirror with transistor M1 and reproduces current I_{ref} multiplied by a factor equal to 2ⁱ.

In an embodiment, switch SWᵢ is closed when bit Sᵢ is at a high logical value “1” and is open when bit Sᵢ is at a low logical value “0”. For example, switch SWᵢ is a MOS transistor, for an example an N channel MOS transistor, the drain of the transistor being coupled or connected to the drain of transistor MCᵢ, the source of the transistor being coupled or connected to node D, and the gate of the transistor receiving bit Sᵢ.

FIG. 4 partially and schematically shows another embodiment of a power detector 30. Power detector 30 shown in FIG. 4 comprises all the elements of power detector 10 shown in FIG. 1 except that transistor M0 is replaced by a transconductor T receiving input voltage V_{RF}, and possibly biasing voltage v_{bias}, and providing current i_{OUT}. Transconductor has a non-linear relation between current jour and input voltage v_{RF}. For example, transconductor T comprises a bipolar junction transistor.

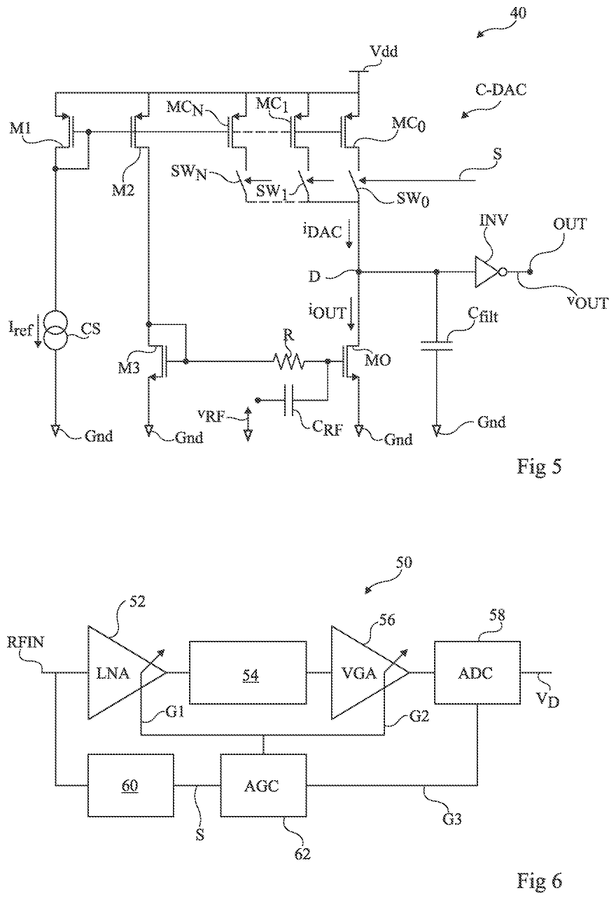

FIG. 5 partially and schematically shows another embodiment of a power detector 40. Power detector 40 shown in FIG. 5 comprises all the elements of power detector 10 with converter C-DAC having the structure shown in FIG. 3. Power detector 40 further comprises: a transistor MOS M2, for example a P channel MOS transistor, the source of transistor M2 being coupled or connected to the source of the high reference potential Vdd, and the gate of transistor M2 being coupled or connected, to the gate of transistor M1; and a transistor MOS M3, for example a N channel MOS transistor, the source of transistor M3 being coupled or connected to the source of the low reference potential Gnd, the gate of transistor M3 being coupled or connected to resistor R and the drain of transistor M3 being coupled or connected to the drain of transistor M2 and to the gate of transistor M3.

In the embodiment shown in FIG. 5, the same current source CS is used to bias the converter C-DAC and to bias transistor M0 . This allows advantageously tracking of offset variations that depend on temperature.

An application of a power detector concerns a radiofrequency receiver or a radiofrequency emitter.

FIG. 6 is a schematic bloc diagram of a radiofrequency receiver 50 receiving ac voltage RFIN that can correspond to an ac voltage obtained from an antenna.

Receiver 50 comprises: a low noise amplifier 52 (LNA) receiving voltage RFIN and amplifying voltage RFIN; a down-conversion unit 54 that receives the amplified voltage provided by low noise amplifier 52 and that converts it down to the baseband frequency; a variable gain amplifier 56 (VGA) that amplifies the down-converted signal; an Analog to Digital converter 58 (ADC) that converts the down-converted and amplified signal into a digital signal V_{D}; a power detector 60, that corresponds to any of power detectors 10, 30 or 40, receiving voltage RFIN and providing digital control values S_{off} and S_{tog} of control signal S upon the detection of the RMS power of voltage RFIN; and an automatic gain control circuit 62 (AGC), that can correspond to the control circuit P previously described, that sends control signal S to power detector 60, and that sends gain control signals G1, G2, G3 to low noise amplifier 52, variable gain amplifier 56, and/or Analog to Digital converter 58, that depend on the detected RMS power of voltage RFIN.

As a variation, instead of determining the RMS power of voltage RFIN power detector 60 can determine the RMS power of the amplified voltage provided by low noise amplifier 52.

According to an embodiment, low noise amplifier 52 comprises at least one MOS transistor.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. An electronic circuit including a power detector for detecting RMS power of an AC voltage, the power detector comprising:
a transconductor configured to receive the AC voltage and to provide a first current to a node with a non-linear relation between the first current and the AC voltage;
a current output digital to analog converter configured to receive a digital signal and to provide a second current to the node;
a low pass filter coupled to the node; and
an inverter having an input coupled to the node and an output configured to provide a binary signal.

2. The electronic circuit according to claim 1, wherein the low pass filter comprises a first capacitor having an electrode coupled to the node.

3. The electronic circuit according to claim 2, wherein the first MOS transistor is an n-channel transistor having a drain connected to the node, a source connected to ground, and a gate coupled to the AC voltage.

4. The electronic circuit according to claim 3, wherein the gate of the first MOS transistor is capacitively coupled to the AC voltage through a capacitor, and is also coupled to receive a bias voltage.

5. The electronic circuit according to claim 1, wherein the transconductor comprises a first MOS transistor.

6. The electronic circuit according to claim 5, wherein the current output digital to analog converter comprises second MOS transistors and controllable switches, each second MOS transistor being coupled in series with one of the controllable switches, each controllable switch being controlled by one bit of the digital signal.

7. The electronic circuit according to claim 6, wherein the current output digital to analog converter further comprises a current source configured to provide a constant reference current and first current mirrors configured to copy the constant reference current multiplied by different multiplying factors to thereby generate the second current, each first current mirror comprising one of the second MOS transistors.

8. The electronic circuit according to claim 7, further comprising a diode mounted third MOS transistor, wherein a gate of the third MOS transistor is coupled to a gate of the first MOS transistor via a resistor and a second current mirror configured to copy the constant reference current to supply the third MOS transistor.

9. The electronic circuit according to claim 1, further comprising an electronic unit configured to receive the binary signal and to vary the digital signal until a toggling of the binary signal occurs.

10. The electronic circuit according to claim 9, wherein the electronic circuit is configured to define a radiofrequency receiver.

11. The electronic circuit electronic circuit according to claim 10,
wherein the transconductor comprises a first MOS transistor; and
further comprising an amplifier configured to receive a radiofrequency AC voltage and to amplify the radiofrequency AC voltage, wherein the amplifier is a transconductance amplifier comprising a fourth MOS transistor, and wherein the first MOS transistor is a scale replica of the fourth MOS transistor.

12. The electronic circuit according to claim 9, wherein the electronic circuit is configured to define a radiofrequency emitter.

13. The electronic circuit electronic circuit according to claim 12,
wherein the transconductor comprises a first MOS transistor; and
further comprising an amplifier configured to receive a radiofrequency AC voltage and to amplify the radiofrequency AC voltage, wherein the amplifier is a transconductance amplifier comprising a fourth MOS transistor, and wherein the first MOS transistor is a scale replica of the fourth MOS transistor.

14. A method for determining RMS power of an AC voltage using a power detector, the method comprising:
receiving the AC voltage and providing a first current to a node with a non-linear relation between the first current and the AC voltage, using a transconductor;
receiving a digital signal at a current output digital to analog converter and providing a second current to the node;
low-pass filtering the node;
inverting a voltage at the node to produce a binary signal; and
varying the digital signal until toggling of the binary signal occurs.

15. The method according to claim 14, further comprising setting the AC voltage at a constant value, varying the digital signal until the toggling of the binary signal occurs, and storing the digital signal for which the binary signal has toggled.
